(19) United States
(12) Patent Application Publication
(10) Pub. No.: US 2012/0293943 A1
(43) Pub. Date: Nov. 22, 2012

(54) USB SOLID STATE STORAGE DRIVE CASING FOR AUTOMATED WRITING AND DISPENSING

(76) Inventor: GORDON P. FLETCHER, La Mesa, CA (US)

(21) Appl. No.: 13/111,142

(22) Filed: May 19, 2011

(51) Int. Cl. H05K 5/00; G06F 1/16

(52) U.S. Cl. 361/679.32; 361/679.01

(57) ABSTRACT

A storage device has a casing with physical and mechanical features that enable an automated dispenser to reliably move the storage device through a loading and dispensing process therewithin. The casing's physical and mechanical features reduce the chance of a user loading the storage device in an automated dispenser incorrectly. The casing may also improve the stacking of storage devices in a dispenser. The casing may also improve the ability of automated dispensers to move the storage device through the writing and dispensing process. The storage devices may be, for example, USB solid state drives (also referred to as flash drives, thumb drives, or the like), Secure Digital (SD) cards, CompactFlash (CF) cards and the like.

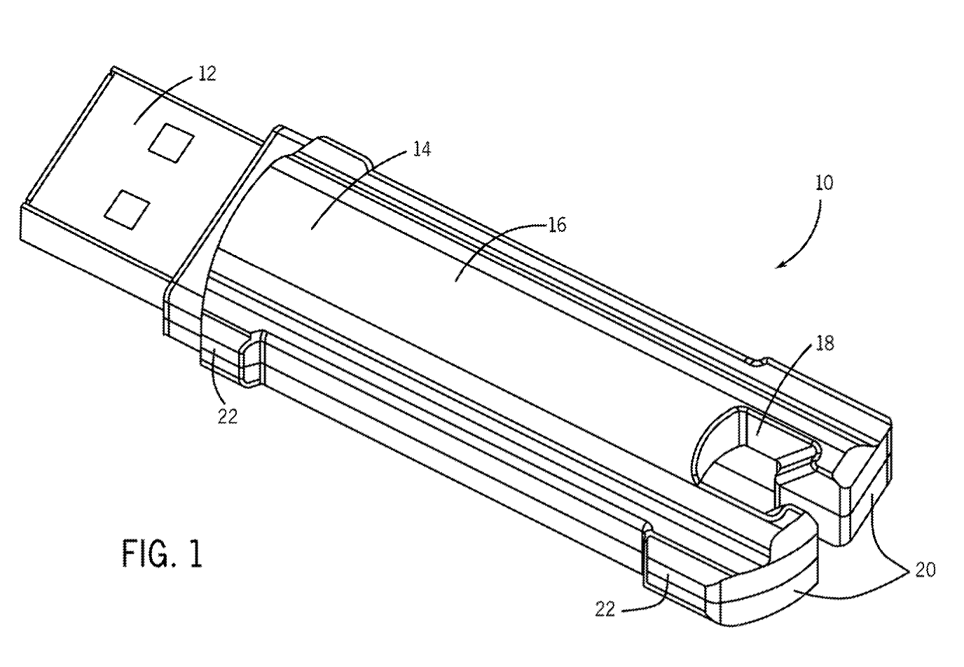

### BACKGROUND OF THE INVENTION

The present invention generally relates to solid-state storage devices, and more particularly to

Currently, a growing number of consumers are turning to solid-state storage devices such as thumb drives and memory cards for their computer storage needs in lieu of optical storage devices, such as CD-ROMs and DVDs, due to the increased durability, reliability, portability, and ease of use of solid-state storage devices.

Furthermore, solid-state storage devices may also allow content providers to deliver more timely and relevant content with more flexibility and lower cost as compared to traditional optical storage devices. As such, content providers such as software firms, electronic game developers, or movie studios may wish to start providing content on solid-state storage devices instead of or in addition to the optical formats they currently provide.

The lack of physical, electro-mechanical, and mechanical features on current universal serial bus (USB) solid state drives makes dispensing unreliable and loading USB solid state drives prone to mistakes. Current USB housings are primarily for cosmetic purposes, such as market branding. Current parts are easily loaded incorrectly and cannot easily be moved throughout an automated dispenser.

As can be seen, there is a need for a storage device having one or more surface features to aid in the loading and automatic dispensing of the storage device.

### SUMMARY OF THE INVENTION

In one aspect of the present invention, a storage device comprises a connector adapted to enable content to be transferred on to or from the storage device; a housing encasing electronics of the storage device; and at least one grasping feature on the housing, the grasping feature adapted to permit an automatic storage device dispenser to automatically load and dispense the storage device.

In another aspect of the present invention, a storage device comprises a connector adapted to enable content to be transferred on to or from the storage device; a housing encasing electronics of the storage device; at least one grasping feature on the housing, the grasping feature adapted to permit an automatic storage device dispenser to automatically load and dispense the storage device; at least one mechanical asymmetry feature, the mechanical asymmetry feature providing an asymmetric design for the housing; and a guiding feature formed in the housing.

These and other features, aspects and advantages of the present invention will become better understood with reference to the following drawing, description and claims.

### BRIEF DESCRIPTION OF THE DRAWINGS

The FIGURE shows a perspective view of a solid-state storage device in accordance with an embodiment of the present invention.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Various inventive features are described below that can each be used independently of one another or in combination with other features.

Broadly, embodiments of the present invention generally provide a storage device having a casing with physical and mechanical features that enable an automated dispenser to reliably move the storage device through a loading and dispensing process therewithin. The casing's physical and mechanical features reduce the chance of a user loading the storage device in an automated dispenser incorrectly. The casing may also improve the stacking of storage devices in a dispenser. The casing may also improve the ability of automated dispensers to move the storage device through the writing and dispensing process. The storage devices may be, for example, USB solid state drives (also referred to as flash drives, thumb drives, or the like), Secure Digital (SD) cards, CompactFlash (CF) cards and the like.

Referring to the FIGURE, a USB flash drive 10 may include one or more features that may help align the drive 10 in an automated dispenser, may help prevent backwards or upside down loading of the drive 10 in an automated dispenser, and may help move the drive 10 through the process of writing and dispensing in the automated dispenser. One example of an automated dispenser useful in the present invention is that of application Ser. No. 12/980,128, filed Dec. 28, 2010, the contents of which are herein incorporated by reference.

The flash drive 10 may include a connector 12, including a ground shield, a case housing 14 and electronics 16 disposed inside the case housing 14. The flash drive 10 may further include a guiding feature 18 which may be a hole formed at the end opposite the connector 12. In some embodiments, the guiding feature 18 may communicate externally of the housing 14. The guiding feature 18 may, for example, permit the flash drive 10 to slide along a rail, such as a T-rail, in the automated dispenser. The guiding feature 18 may enable the flash drive 10 to be easily stacked, may reduce the risk of incorrect loading, and may align the flash drive 10 for use in the automated dispenser.

The flash drive 10 may further include one or more mechanical asymmetry features 20. In some embodiments, the mechanical asymmetry features 20 may include different surface shapes on specific locations of the housing 14. For example, at the end opposite of the connector 12, one side of the end may be rounded with a particular radius of curvature while the other side of the end may be more angular, having, for example, sharp angles. The mechanical asymmetry features 20 may reduce the ability for a user to load the flash drive 10 upside down or backward in to an automated dispenser.

The flash drive 10 may further include one or more graspable features 22. The graspable features 22 may include, for example, protrusions on one or both sides of the flash drive 10, having a defined indentation therebetween. In some embodiments, the graspable features 22 may be formed on a top and/or bottom surface of the housing 14. The graspable features 22 may enable an automated dispenser to reliably move the flash drive 10 through the writing and dispensing process.

The features of the flash drive 10, such as the graspable features 22, may be molded at the time of forming the housing 14, or may be added on to an existing flash drive casing. Similarly, the mechanical asymmetry features 20 may be molded into the housing 14 or may be added on after the housing molding is complete.

While the above description refers to flash drives, other storage devices may be configured with the features described herewithin to permit those storage devices to operate in an automated dispenser. For example, SD, CF, Memory Stick and other solid state storage devices may be used within the scope of the present invention.

It should be understood, of course, that the foregoing relates to exemplary embodiments of the invention and that modifications may be made without departing from the spirit and scope of the invention as set forth in the following claims.

What is claimed is:

1. A storage device comprising:
a connector adapted to enable content to be transferred on to or from the storage device;
a housing encasing electronics of the storage device; and
at least one grasping feature on the housing, the grasping feature adapted to permit an automatic storage device dispenser to automatically load and dispense the storage device.

2. The storage device of claim 1, wherein the grasping feature includes protrusions, spaced apart and extending from at least one side of the housing.

3. The storage device of claim 1, further comprising at least one mechanical asymmetry feature, the mechanical asymmetry feature providing an asymmetric design for the housing.

4. The storage device of claim 3, wherein the at least one mechanical asymmetry feature includes a rounded corner at one side of an end opposite the connector, and an angled corner at an opposite side of the end of the connector.

5. The storage device of claim 1, further comprising a guiding feature formed in the housing.

6. The storage device of claim 5, wherein the guiding feature includes a hole formed in the housing at an end opposite the connector, and the hole communicates with an exterior of the housing.

7. The storage device of claim 1, wherein the storage device is a universal serial bus (USB) solid state storage device.

8. A storage device comprising:
a connector adapted to enable content to be transferred on to or from the storage device;
a housing encasing electronics of the storage device;
at least one grasping feature on the housing, the grasping feature adapted to permit an automatic storage device dispenser to automatically load and dispense the storage device;
at least one mechanical asymmetry feature, the mechanical asymmetry feature providing an asymmetric design for the housing; and
a guiding feature formed in the housing.

9. The storage device of claim 8, wherein the guiding feature includes a hole in an end of the housing opposite the connector, the hole communicating with an exterior of the housing.

10. The storage device of claim 8, wherein:
the grasping feature includes protrusions, spaced apart and extending from at least one side of the housing; and
the at least one mechanical asymmetry feature includes a rounded corner at one side of an end opposite the connector, and an angled corner at an opposite side of the end of the connector.
